(19) United States
(12) Patent Application Publication
(10) Pub. No.: US 2017/0131357 A1
(43) Pub. Date: May 11, 2017

(54) METHOD AND APPARATUS FOR MONITORING AND DETERMINING ENERGY STORAGE DEVICE CHARACTERISTICS USING FIBER OPTICS

(71) Applicants: Patricia NIEVA, Mississauga (CA); Amir KHAJEPOUR, Waterloo (CA)

(72) Inventors: Patricia NIEVA, Mississauga (CA); Amir KHAJEPOUR, Waterloo (CA); Krishna IYER, Waterloo (CA); Abdulrahman GHANNOUM, Waterloo (CA); Hamidreza ALEMOHAMMAD, Mississauga (CA)

(21) Appl. No.: 14/935,962

(22) Filed: Nov. 9, 2015

(51) Int. Cl. G01R 31/36; G01R 15/24

(52) U.S. Cl. CPC G01R 31/3606; G01R 31/3679; G01R 15/241

(57) ABSTRACT

A system for monitoring characteristics of an energy storage device including the energy storage device, an optical fiber cable having a first end and a second end, the optical fiber cable embedded within the energy storage device, and a sensor interrogation system, the sensor interrogation system connected to at least one of the first end or second end of the optical fiber cable.

### FIELD OF THE DISCLOSURE

The current disclosure is generally directed at energy storage devices and, more specifically, is directed at a method and apparatus for monitoring and determining energy storage device characteristics using fiber optics.

### BACKGROUND OF THE DISCLOSURE

Rechargeable batteries such as lithium-ion and nickel-cadmium cells have found use in a wide variety of applications. The growth of electric and hybrid-electric vehicles (EV and HEV, respectively) has driven the need for improved battery technologies, especially lithium-ion batteries (LIB). The major advantages of LIBs are high energy density, short priming time, low maintenance, and the capability for supplying a high current. Battery packs, which are the combination of multiple cells, are among the most critical components in electric vehicles. The individual cells in each battery pack are continuously controlled and balanced by a central Battery Management System (BMS) to ensure optimum performance and to protect them from operation outside their safe conditions, e.g., over-temperature, over-current, etc.

BMS relies on measurement data such as voltage, current, and temperature to estimate the State of Charge (SOC), based on Open Circuit Voltage (OCV), and the State of Health (SOH). However, the charge estimation, which may be performed by methods such as Kalman filtering, is susceptible to measurement error accumulation and numerical uncertainties. As a result, a safety factor is applied to the design of storage devices or battery cells to compensate for these uncertainties. This safety factor can make the battery packs larger and heavier which also results in the increase of the negative environmental impacts when battery cells are disposed and recycled at the end of their effective life cycle. A major challenge with existing lithium-ion battery technologies is the need for reliable and real-time monitoring of battery performance and health. Improving the reliable estimation of the energy in a battery can potentially reduce the cost and weight of HEVs and EVs while improving reliability and lifetime of the battery system.

Given the complex electrochemical environment of a battery cell, an in-situ sensor embedded inside the cells has the advantage of direct monitoring of the changes in electrochemistry compared to the indirect voltage and current measurements. The battery cell is a corrosive environment that is not friendly for many electronic sensors (such as thin film and MEMS based piezoelectric or piezoresisitive sensors). Even hermetically sealed sensors cannot be reliably used in battery cells due to their susceptibility to Electromagnetic Interference (EMI).

Therefore, there is provided a novel method and apparatus for monitoring and determining energy storage device characteristics using fiber optics.

### SUMMARY OF THE DISCLOSURE

The disclosure is directed at a system for determining energy storage device characteristics, the system including modified optical fibers embedded inside of the energy storage device, such as a battery cell, which act as a sensor. The system further includes a sensor interrogation system combining optoelectronic and other electronic components to convert received optical signals to electrical signals, translate them to measurement values, and to transmit these values to other components in a battery management system.

In one embodiment, an optical based sensor device made of non-conductive materials (e.g., glass) is contemplated. The optical fiber has advantages of immunity to EMI, robustness to corrosive environments, and small form factor.

Optical fiber sensors which are, preferably, based solely on the propagation of optical waves can be embedded inside energy storage devices, such as battery cells, for high fidelity cell condition monitoring without having the optical signal deteriorated by the electro-chemistry of the battery cell.

The disclosure is directed at a system and method for the monitoring of an energy storage device using sensors which are part of an optical fiber. In one embodiment, the system is directed at the monitoring of lithium-ion batteries for HEV and EV applications. However, the application of the disclosure is not limited to lithium-ion batteries or to HEV and EV applications.

The parameters of interest that are to be estimated or measured from an energy storage device include, but are not limited to, releasable capacity, the state-of-charge (SOC), state-of-health (SOH), temperature, electrolyte chemistry and chemical properties of energy storage device components, and volume change of battery and battery components. The SOC is an estimate of the amount of releasable energy stored in the battery. In EVs, an accurate measurement of this parameter is necessary for the estimation of the driving range of the vehicle. The SOH is an estimate of the health of the battery. As a battery ages, the performance of the battery deteriorates, reducing the overall capacity of the battery and the estimation of the health of the battery is necessary for reliable SOC and driving range estimation. The battery temperature is an important parameter to measure. Non-ideal temperatures of a battery can cause undesirable aging and capacity fade. Additionally, the volume of the battery cell is a function of the electrode expansion and contraction and continuously changes with the battery SOC. There are also dynamic changes in the electrolyte chemistry in terms of the ion concentration which is also affected by the SOC. Measurement of these parameters is important for an EV to improve long-term reliable performance.

### DESCRIPTION OF THE DRAWINGS

FIG. 1 is a schematic diagram of a first embodiment of a system for battery monitoring for use in transmission mode sensing;

FIG. 2 is a schematic diagram of another embodiment of how an optical fiber cable is embedded within a battery cell for use in transmission mode sensing;

FIG. 3 is a schematic diagram of a sensor interrogation system for use in transmission mode sensing;

FIG. 4 is a schematic diagram of an embodiment of a system for battery monitoring for use in reflection mode sensing;

FIG. 5 is a schematic diagram of an embodiment of how an optical fiber cable is embedded within a battery cell for use in reflection mode sensing;

FIG. 6 is a schematic diagram of a sensor interrogation system for use in reflection mode sensing;

FIG. 7 is a schematic diagram of how the optical fiber cable may be terminated within the battery cell for use in reflection mode sensing;

FIG. 8 is a schematic diagram of an optical fiber sensor;

FIG. 9 is a schematic diagram of an optical fiber cable embedded within a battery cell;

FIG. 10 is schematic diagram of another embodiment of the optical fiber sensor;

FIG. 11 is a schematic diagram of a further embodiment of the optical fiber sensor;

FIG. 12 is a schematic diagram of yet another embodiment of the optical fiber sensor;

FIG. 13 is a schematic diagram of the optical fiber sensor embedded between a cathode and a separator of the battery cell;

FIG. 14 is a schematic diagram of the optical fiber sensor embedded within a cathode;

FIG. 15 is a schematic diagram of the optical fiber sensor embedded within the anode;

FIG. 16 is a schematic of the optical fiber sensor embedded in the separator;

FIG. 17 is a schematic diagram of optical fiber cable including multiple optical fiber sensors;

FIG. 18 is a schematic diagram of a first embodiment of an opto-electronic circuit;

FIG. 19 is a schematic diagram of another embodiment of an opto-electronic circuit;

FIG. 20 is a schematic diagram of yet another embodiment of an opto-electronic circuit;

FIG. 21 is a schematic diagram of an optical circulator;

FIG. 22 is a schematic diagram of a battery monitoring system in use with multiple battery cells;

FIG. 23 is a schematic diagram of another embodiment of a battery monitoring system for use with multiple battery cells;

FIG. 24 is a schematic diagram of yet another embodiment of a battery monitoring system for use with multiple battery cells;

FIG. 25 is a flowchart outlining a method of energy storage device characteristic monitoring;

FIG. 26 is a schematic diagram of a system for determining battery characteristics;

FIG. 27 is a flowchart outlining a method for determining battery characteristics;

FIG. 28 is a schematic diagram of a second system for determining battery characteristics;

FIG. 29 is a schematic diagram of another system for determining battery cell charge;

FIG. 30 is a flowchart outlining another method for determining battery cell charge;

FIG. 31 is a schematic diagram of a system for determining battery cell charge; and

FIG. 32 is a schematic diagram of yet another embodiment of a battery monitoring system for use with multiple battery cells.

### DETAILED DESCRIPTION OF THE PREFERRED EMBODIMENTS

The disclosure is directed at a method and apparatus for monitoring and/or measuring the characteristics of an energy storage device, such as, but not limited to, a battery cell or a fuel cell. The apparatus includes a sensor interrogation system which is connected to at least one end of an optical fiber cable (which includes at least one optical fiber sensor) embedded within the energy storage device, such as a battery cell. Depending on the setup of the apparatus, the apparatus can operate in either a transmission mode or a reflection mode.

In one embodiment, the characteristic or characteristics being monitored in the energy storage device may include releasable capacity, State of Charge (SOC) and/or the State of Health (SOH), temperature, electrolyte chemistry (such as density, ion concentration, chemical composition, etc.), chemical properties of energy storage device components, electrode expansion, temperature or cell volume of the energy storage device. In one embodiment, the optical fiber cable may contain a multitude of sensing points to monitor one or more characteristics simultaneously in the energy storage device. The sensor interrogation system then demodulates the optical signals from each of the sensing points (as described below).

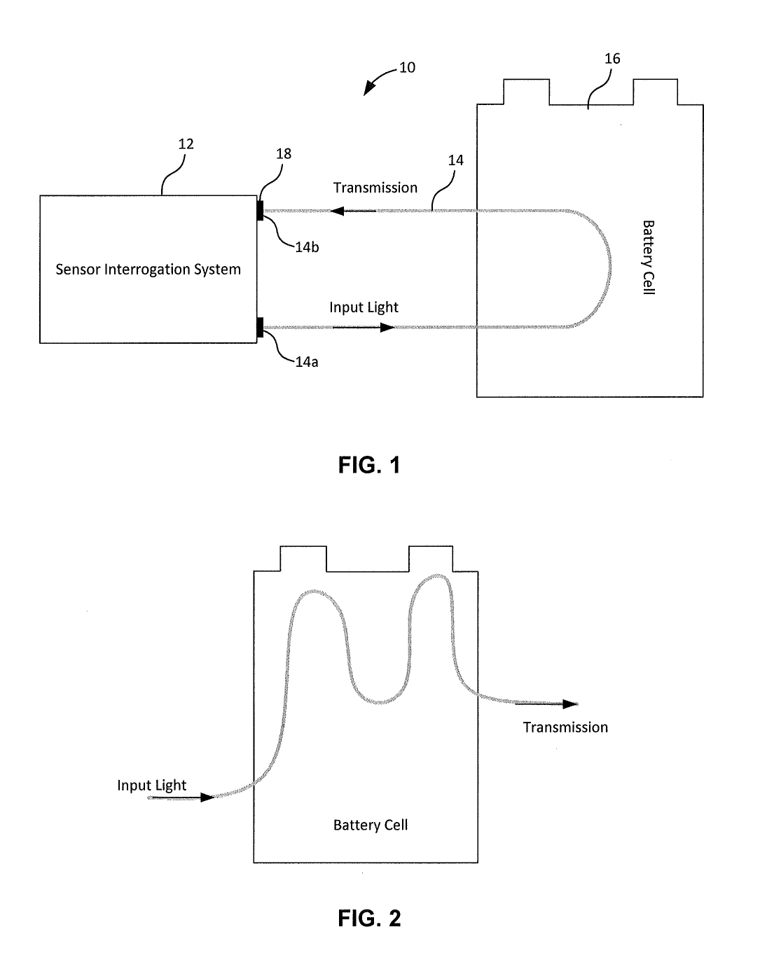

Turning to FIG. 1, a schematic diagram of a first embodiment of a system for energy storage device characteristic monitoring is shown. In this embodiment, which may be seen as a transmission mode sensing embodiment, the apparatus, or system, 10 includes a sensor interrogation system 12 which is connected to both ends of an optical fiber cable 14 which has a portion of the cable embedded within an energy storage device, such as a battery cell 16. One end of the optical fiber cable 14 may be seen as a light output end 14a and the other end may be seen as a light input end 14b. The embodiment may be seen as a transmission mode sensing embodiment since both ends of the optical fiber cable 14 are connected to the sensor interrogation system 12 such that light is transmitted out of the light output end 14a through the optical fiber cable 14 and then returned through the light input end 14b. FIG. 2 is a schematic diagram of another embodiment of how the optical fiber cable 14 may be embedded within the battery cell 16.

Although the battery cell 16 is not necessarily part of the system for energy storage device monitoring, as the optical fiber cable 14 is embedded within the battery cell 16 in the current embodiment, it is assumed that, in the current embodiment, the battery cell 16 forms part of the system 10.

The ends of the optical fiber cable 14a and 14b are preferably terminated with optical connectors 18 that enable effective coupling of the optical fiber cable 14 to the interrogation system 12. Although not shown, the end of the optical fiber cable 14 may also be spliced to the sensor interrogation system 12 using standard fiber fusion splicers or mechanical splicers.

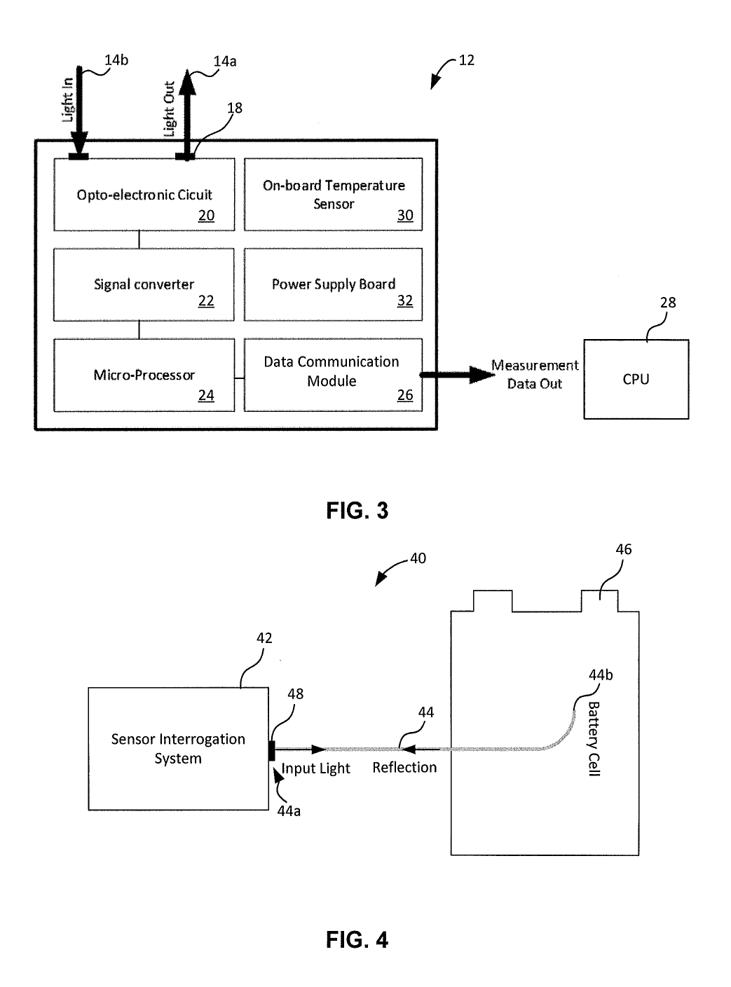

FIG. 3 is a schematic diagram of one embodiment of a sensor interrogation system for use in transmission mode sensing.

The sensor interrogation system 12 includes the optical connectors 18 for receiving the two ends 14a and 14b of the optical fiber cable 14. An opto-electronic circuit 20 is connected to the ends of the optical fiber cable 14 to transmit light out (via the light output end 14a) and to receive light in (via the light input end 14b). The opto-electronic circuit 20 includes a light source (not shown) for providing light to the optical fiber cable 14. The opto-electronic circuit may also include a detector such as a photo detector (not shown) to convert the light received from the sensor to an electric signal. The opto-electronic circuit 20 is further connected to a signal converter 22 which can translate the analog signal generated in the opto-electronic circuit by the he light input end 14b to a representative digital signal for a micro-processor 24 or can translate an instruction signal from the micro-processor 24 to control a light source generating light for transmission along the optical fiber cable 14. In other words, the micro-processor 24 can be used to control the light source driver (or current driver) to regulate the optical power generated by the light source. Some light sources such as laser sources typically require this control system. In other types of light sources (e.g., LED light sources) the mechanism is simpler but a current driver is still required. In another embodiment, the microprocessor may convert a sensed voltage signal to measures of the releasable capacity, SOC, SOH, temperature, electrolyte chemistry, chemical properties of energy storage device components, volume change, etc. The micro-processor 24 is further connected to a data communication module (such as a data interfacing bus 26) for transmission of information (including the representative digital signal) to and from an external processor 28 or computer. The data communication module may be compatible with communication technologies such as, but not limited to, Ethernet, WiFi, Serial Port, USB, CAN Bus, Profibus, Profinet, etc. In another embodiment, the data may not be completely processed at the micro-processor level. In this embodiment, the raw data is transmitted through the data communication module to an external processing unit which can be a personal computer (PC) or an external processing unit.

The sensor interrogation system 12 may further include an on-board temperature sensor 30 and a power supply board 32, although other methods of powering the interrogation system 10 are contemplated. Within the sensor interrogation system 12, the on-board temperature sensor 30 may include a temperature controller unit to control the temperature of the electronic and opto-electronic components. The on-board temperature sensor measurement data can be used to correct the light detector measurement signals and compensate for temperature changes.

Other components of the sensor interrogation system (which are not shown but which may be integrated within one of the disclosed components or as a stand-alone component within the system 12) include, but are not limited to, power conditioning electronics to drive the light source or amplification electronics to amplify the opto-electronic circuit output signals.

In one embodiment, the opto-electronic circuit 20 includes the light source to illuminate the optical fiber cable 14. Different types of wide-band and narrow band light sources can be used which include, but are not limited to, light emitting diodes (LEDs), super luminescent diodes (SLED), fixed wavelength lasers, tunable lasers, multi-wavelength lasers, Fabry-Perot lasers, or amplified spontaneous emission (ASE) light sources. The light source may require a driver to control its wavelength and intensity. Additionally, the sensor interrogation system 12 may include at least one optical detector to convert the optical signal, or light, received from the optical fiber cable 14 to an electric signal. This detector may be either a broadband intensity sensor (e.g. photo-detector) or a wavelength resolved sensor (e.g. spectrometer or optical spectrum analyzer). An additional light detector may be included to compensate for light source instability and power fluctuations.

Within the sensor interrogation system 12 are demodulating mechanisms or apparatuses for demodulating the optical signals received from the optical fiber cable 14. These mechanisms are preferably based on Wavelength Division Multiplexing (WDM), Time Division Multiplexing (TDM) or a combination of both. In WDM, each sensing point (part of the optical fiber cable) has a unique wavelength that is de-multiplexed by optical filters such as band-pass filters. The opto-electronic circuit may contain a tunable WDM filter to de-multiplex different wavelengths of light which are received. The tunable WDM control signal is generated by the micro-processor 24 in the interrogation system 12. In TDM, the optical signal from multiple sensing points is de-multiplexed based on the time of flight of the optical signal. This will be described in more detail below with respect to a method of energy storage device monitoring or energy storage device characteristic sensing.

In another embodiment, the opto-electronic circuit may contain multiple fixed wavelength WDM filters or an array of filters to de-multiplex different wavelengths of light. In this embodiment, an array of light sensors converts the optical signal from each sensing point to an electric signal.

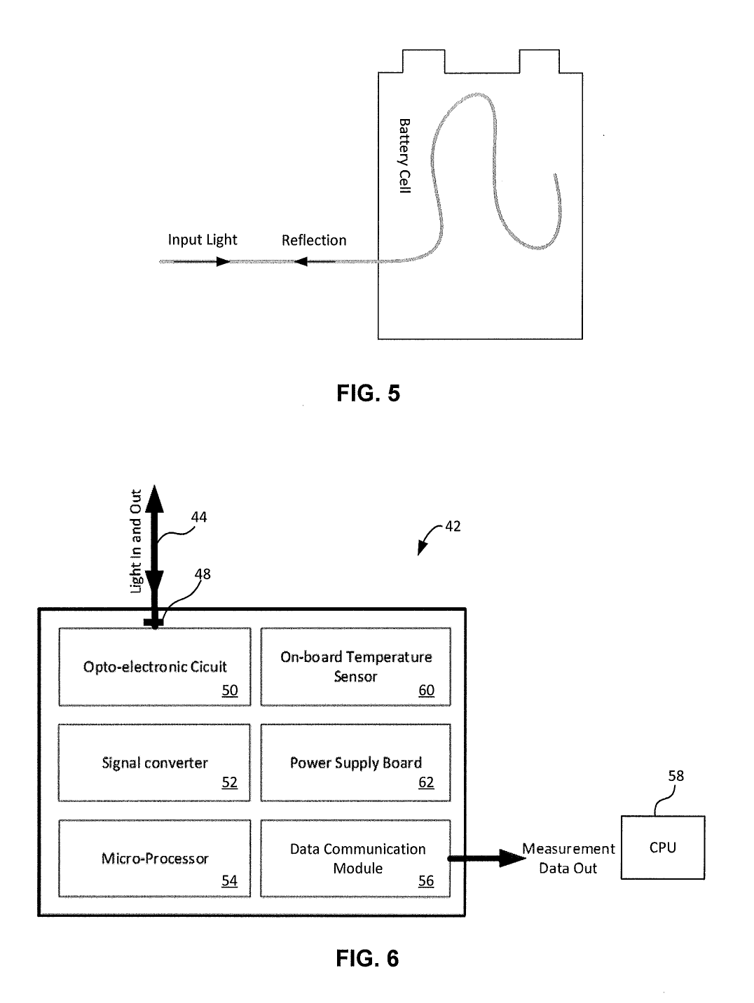

Turning to FIG. 4, a schematic diagram of a second embodiment of a system for energy storage device characteristic monitoring is shown. In this embodiment, the system 40 includes a sensor interrogation system 42 which is connected to one end of an optical fiber cable 44. In the current embodiment, the end connected to the sensor interrogation system may be seen as the light input end and the light output end 44a. A portion of the optical fiber cable 44 (along with a second end 44b of the cable 44) is embedded within an energy storage device, such as a battery cell 46. Further detail with respect to the embedding of the cable within the battery cell 46 Will be described below. In use, light is transmitted from the sensor interrogation system 42 through the optical fiber cable 44 and then reflected back towards the sensor interrogation system 42 when it reaches the second end of the cable. FIG. 5 is another embodiment of how the optical fiber cable 44 may be embedded within the battery cell 46.

The end of the optical fiber cable 44 which is connected to the interrogation system 42 is preferably terminated with an optical connector 48 that enables effective coupling of the optical fiber cable 44 to the sensor interrogation system 42.

Turning to FIG. 6, a schematic diagram of a sensor interrogation system for use in reflection mode sensing is shown. The sensor interrogation system 42 is similar to the interrogation system 12 of FIG. 3 with the difference being that only one end of the optical fiber cable 44 is connected to an opto-electronic circuit 50. The interrogation system 42 further includes a signal convertor 52, a micro-processor 54, a data communication module (such as a data interfacing bus) 56, an on-board temperature sensor 60 and a power supply board 62 which all function similarly or identically to the like parts of the transmission mode interrogation system 12. The interrogation system 42 is also connected to an external processor 58.

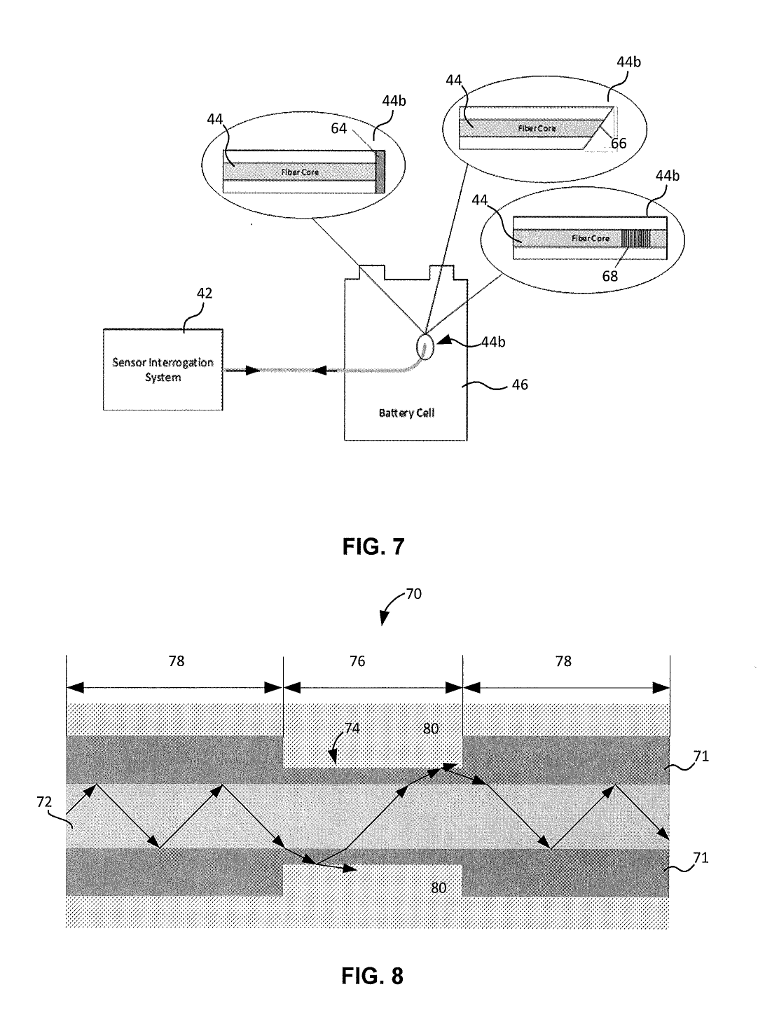

Turning to FIG. 7, schematic diagrams of how the optical fiber cable may be terminated at the second end 44b within the battery cell for the embodiment of FIG. 4 or 5 are shown. In one embodiment, a reflective coating 64 is deposited at the second end 44b of the optical fiber cable 44. In another embodiment, the second end 44b of the optical fiber 44 is cleaved 66 at an angle to reflect the light back towards the sensor interrogation system 42. In yet another embodiment, an optical grating 68 is included at the second end 44b of the optical fiber cable 44.

Turning to FIG. 8, a schematic diagram of a portion of the optical fiber cable embedded within the energy storage device is shown. As shown, the optical fiber cable 14 or 44 includes at least one sensing point representing the optical fiber sensor 70. The optical fiber sensor 70 may be seen as an optical fiber based evanescent wave sensor.

The optical fiber cable 14 (or 44), which may be a single-mode or multi-mode fiber, is modified by a partial removal of cladding 71 that surrounds a core 72 of the optical fiber cable 14 (or 44) to produce the sensing point 74 or sensing region of the optical fiber cable 14. The partial removal of the cladding may be performed mechanically (i.e. controlled abrasion and polishing), chemically (i.e. wet or dry etching), or by using laser microfabrication (i.e. femtosecond laser microfabrication). The removal of the cladding 71 produces a modified optical fiber cable area 76 and an unmodified optical fiber cable area 78. Other manufacturing methods, including but not limited to, fiber tapering (i.e., heating and stretching fiber at the same time), can also be used to make the sensing sections on the fiber optic.

The cladding 71 is preferably made of a material of lower refractive index than the core 72 which allows propagation of the light across the core 72 by enabling total internal reflection at the interface between the core 72 and the cladding 71. Upon total internal reflection, an evanescent wave is created which decays exponentially into the cladding 71. The sensing mechanism in this case can be based on total-internal-reflection occurring at the core/cladding and cladding/external medium. By reducing a thickness of the cladding 71, light propagating within the optical fiber core 72 can also tunnel out of the optical fiber cable 14 or 44 based on the interaction of the evanescent wave with external media 80 (such as the battery cell) surrounding the optical fiber cable 14. Any change in the properties of the external media (i.e. reflectivity, concentration, density, etc.) results in a change in the evanescent wave which allows the properties of the external media to be sensed, detected or calculated by analyzing the change in the evanescent wave properties by the sensor interrogation system. Without changing the generality of the system, the sensor 70 may also be fabricated by complete removal of the cladding and also partial etching of the optical fiber core 72. The amount of cladding 71 removed provides various types of optical fiber sensors.

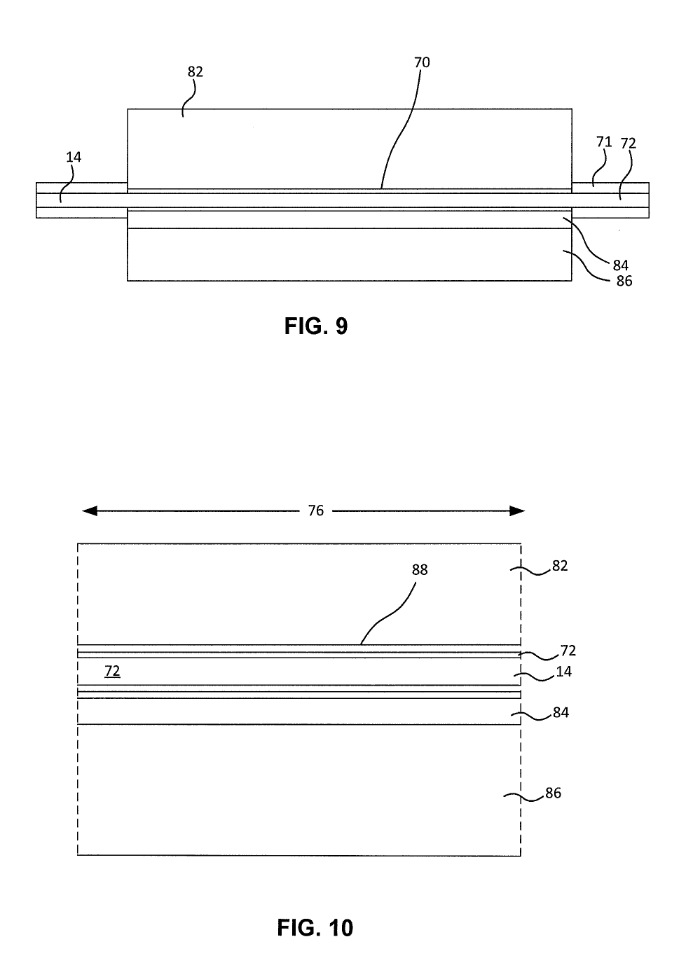

Turning to FIG. 9, a schematic diagram of a first embodiment of how an optical fiber cable (or optical fiber sensor) is embedded within an energy storage device, such as a battery cell, is shown. The optical fiber sensor 70 may be used for battery cell characteristics or parameter measurement from within the battery cell. These characteristics may include, but are not limited to, releasable energy, SOC, SOH, cell temperature, electrolyte chemistry, cell components chemical properties, ion concentration, cell volume change, etc.

In one embodiment, the optical fiber cable with partially removed cladding or tapered fiber, or the optical fiber sensor 70, as described in FIG. 8, is embedded in the layers of a battery cell 16 as shown in FIG. 9. The battery cell 16 typically includes an anode section 82, a separator section 84 and a cathode section 86. In the current figure, the optical fiber cable 14 (or the optical fiber sensor 70) is embedded within the anode section 82 of the battery cell 16. In use, the transmitted optical power or light in the optical fiber cable 14 is attenuated at the removed cladding region of the optical fiber cable by the absorption of the evanescent waves at an interface between the anode section 82 of the battery cell and the optical fiber cable.

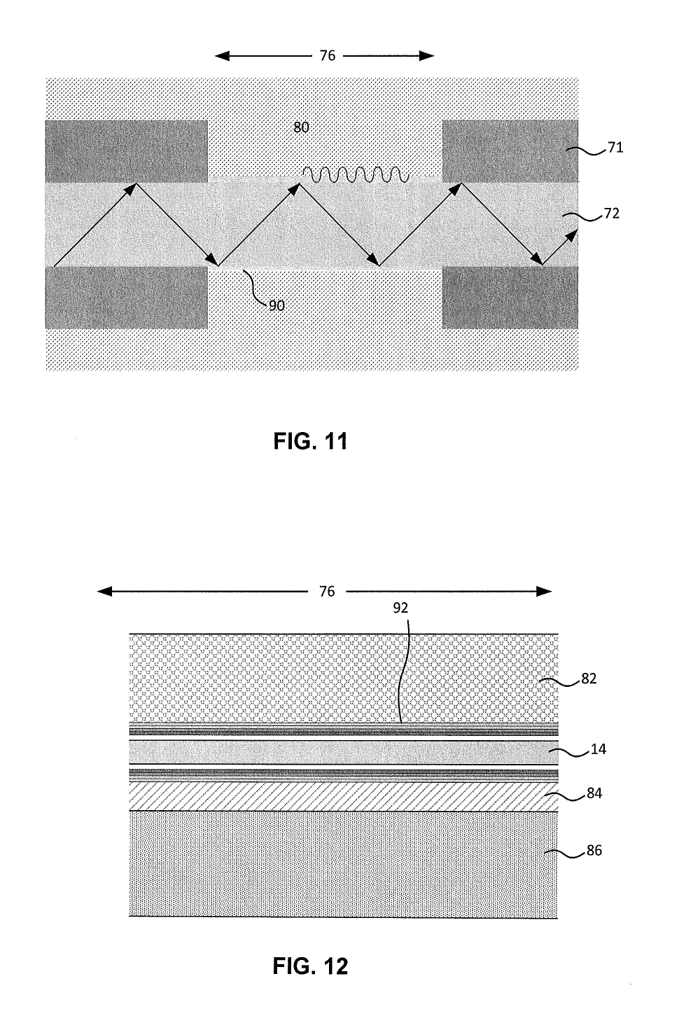

In another embodiment (as shown in FIG. 10), the modified area 76 may be recoated with a functional material 88 whose optical and/or mechanical properties may be modified by the measured parameters which also results in a change in the evanescent wave properties and transmission power attenuation. In another embodiment, the reduced modified area 76 may be coated with thin metal films 90, such as shown in FIG. 11. This results in Plasmonic excitation at the interface between the optical fiber cable 14 and the thin metal film 90 and transmission power attenuation due to the changes in releasable capacity, SOC, SOH, temperature, electrolyte chemistry, chemical properties of energy storage device components, ion concentration, or volume change. In another embodiment, the surface of the optical fiber cable in the modified area 76 may be coated by metal nano-particles 90 or a matrix containing metal nanoparticles to generate localized surface Plasmon resonance (LSPR) at the interface between the optical fiber cable and the metal interface. In the case of LSPR and SPR excitation, the spectral intensity of the transmitted light is changed such that it can be demodulated with optical power measurement in the opto-electronic circuit. In another embodiment, the modified area of the optical fiber cable 14 may be coated with a nano-structured layer (i.e. nano-particles or nano-rods) to generate Surface Enhanced Raman Scattering (SERS) which results in light absorption at certain frequencies. In each of these embodiments, the enhancements allow for an adjusted wave spectrum for measurement by the sensor interrogation system to determine certain characteristics of the battery cell.

In another embodiment, the modified area 76 of the optical fiber cable 14 may be coated with a fluorescent dye integrated in a polymer matrix such as Polydimethylsiloxane (PDMS). The fluorescent molecules can be excited by passing ultraviolet (UV) or visible light through the optical fiber cable. The fluorescence emission spectrum (i.e., peak wavelength and bandwidth) is modified by temperature which affects the transmitted optical power. The transmitted optical power can be correlated to temperature variation of the battery cell or the energy storage device.

Turning to FIG. 12, another embodiment of an optical fiber sensor is shown. In this embodiment, the modified area 76 of the optical fiber cable 14 may be coated with periodic layers 92 (i.e., materials with different thickness and optical properties) to form a grating structure. Changes in the external media can result in a spectral changes which can be detected by measuring the transmission power by the sensor interrogation system.

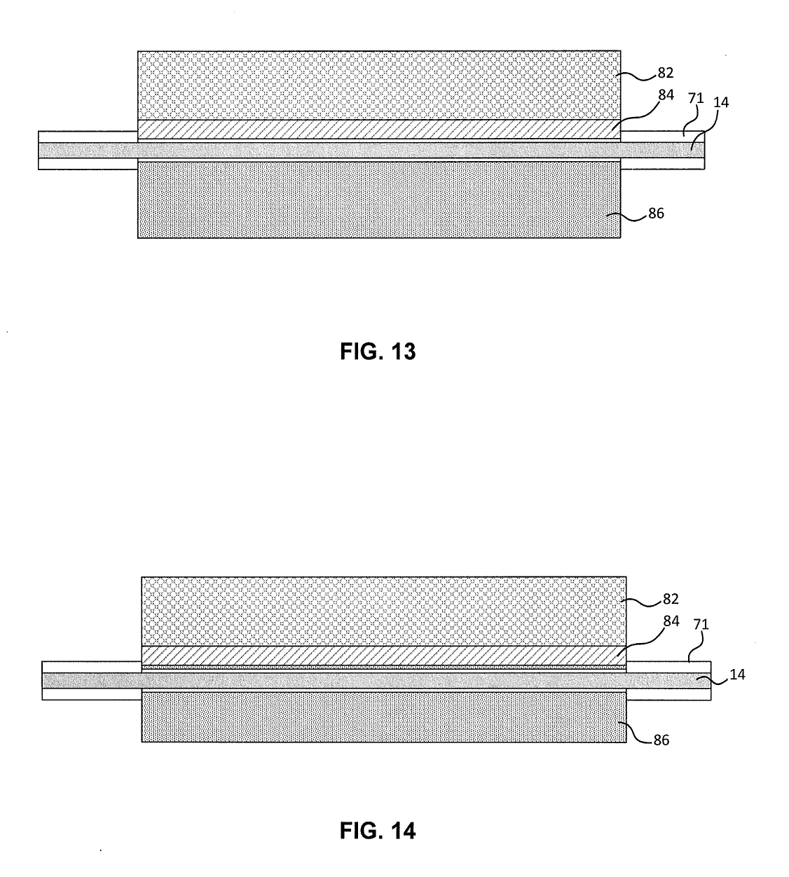

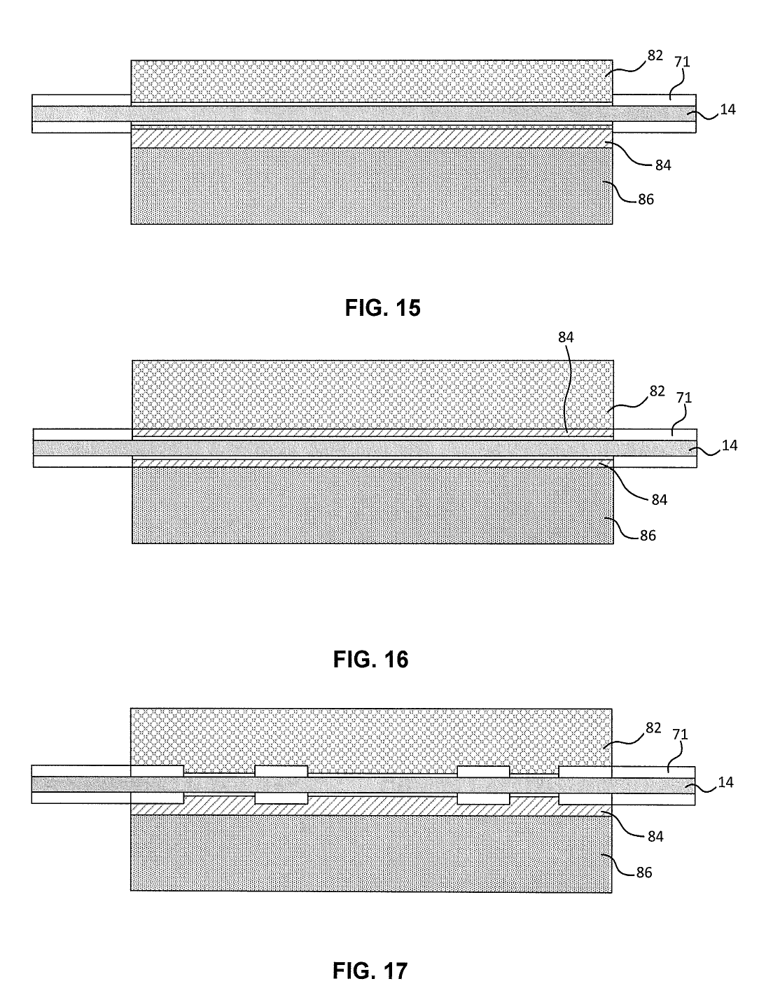

Turning to FIGS. 13 to 16, further schematic diagrams of an optical fiber sensor (or optical fiber cable with cladding removed) embedded in a battery cell are provided. In FIG. 13, the optical fiber sensor is embedded between the cathode and the separator; in FIG. 14, the optical fiber sensor is embedded within the cathode; in FIG. 15, the optical fiber sensor is embedded within the anode and in FIG. 16, the optical fiber sensor is embedded in the separator.

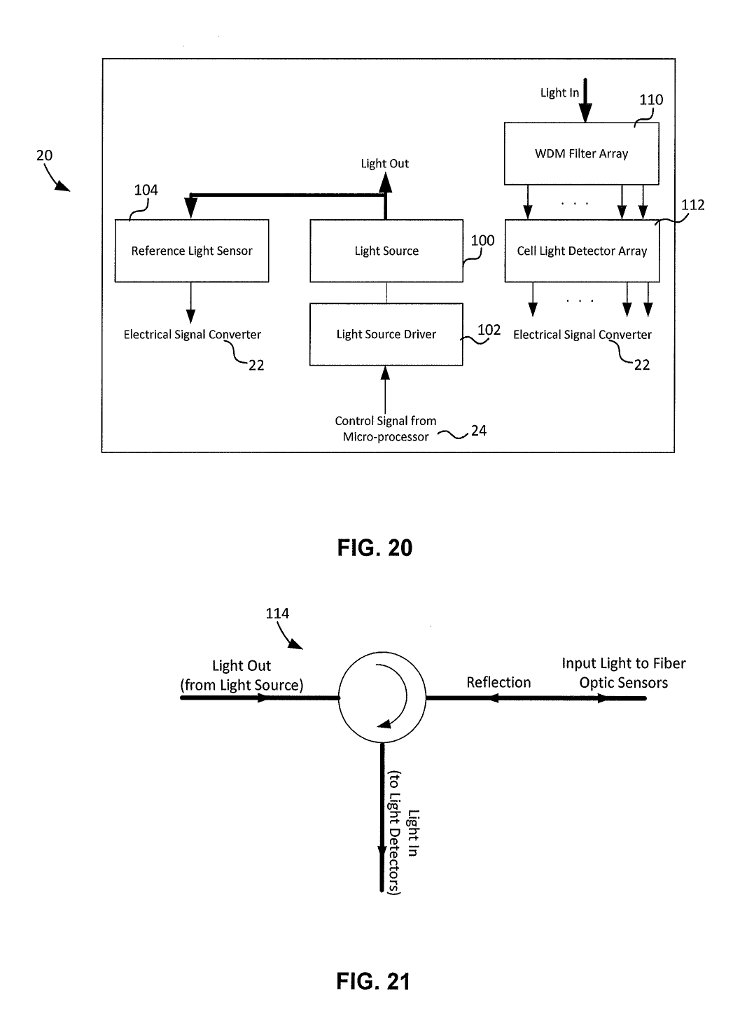

Turning to FIG. 17, another embodiment of an optical fiber sensor embedded within a battery cell is shown. In this embodiment, the optical fiber cable includes a plurality of modified areas 76 such that there are multiple sensors within a single optical fiber cable. These multiple sensors may then sense different characteristics or parameters of the battery cell. All the above sensing points, or modified areas, can be fabricated in a single strand of single-mode or multi-mode optical fiber to build the multi-parameter fiber optic sensor. The integration of multiple sensing points can also be realized by fusion splicing multiple fiber sensors. In one embodiment, the optical fiber cable has multiple sensing zones placed in series along the cable 14 (or 44) as shown in FIG. 17. In this embodiment, one of the multiple sensing zones may be used to determine a temperature within the energy storage device. The sensing points in each zone can be selected from different signal transduction mechanisms as discussed above. Without changing the generality of the multi-parameter sensing fiber cable 14, the multi-parameter sensing fiber cable 14 can be embedded in the battery cell in a variety of configurations including being embedded in the anode, the cathode of the separator, squeezed between the cathode and the separator, or squeezed between the anode and the separator and is not restricted to a single location as shown in previous figures. In multiple-parameter sensing cables 14, each sensing point operates at a specific wavelength which is different than the other sensing points. In this case, the sensor wavelengths are then de-multiplexed using Wavelength Division Multiplexing (WDM), such as disclosed with respect to FIG. 20. All or some of the sensing points can also be operated by the same wavelength of light where they can be de-multiplexed using Time Division Multiplexing (TDM).

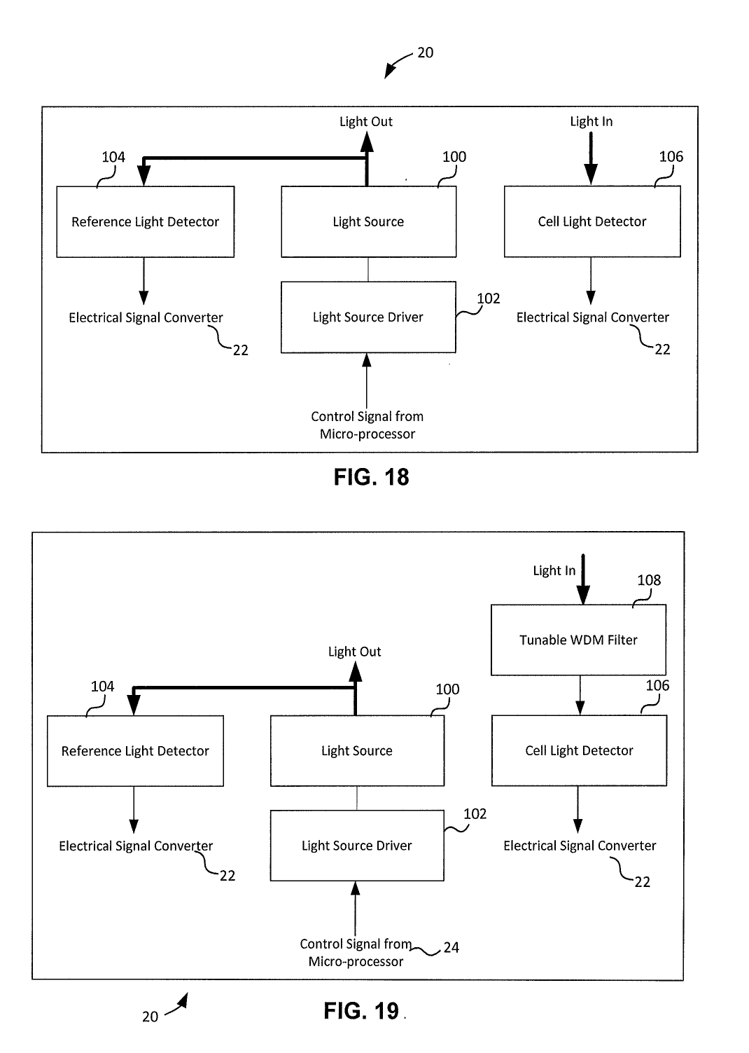

Turning to FIGS. 18 to 20, different embodiments of the opto-electronic circuit 20 or 50 is shown. In FIG. 18, the opto-electronic circuit 20 includes a light source 100 which may be a light emitting diode (LED), an organic LED (OLED), a laser or the like connected to a light source driver 102 which receives control signals from the micro-processor 24. It will be understood that reference to the components of FIG. 3 also applies to the similar components of FIG. 6. In operation, the light source 100 transmits light out along the optical fiber cable 14 into the battery cell 16. The circuit 20 further includes a reference light detector 104, such as, but not limited to, a photo-detector, an optical spectrum analyzer or a spectrometer, which is in communication with the electrical signal converter 22. The use of a reference light detector is optional and it helps to compensate for the optical power fluctuations in the light source to increase the accuracy of measurements. A cell light detector 106 (which may be the same as the reference light detector 104) receives the light which is returned along the optical fiber cable 14 and then transmits the light to the electrical signal converter 22.

In FIG. 19, which may be seen as an opto-electronic circuit with a tunable WDM filter, the circuit 20 is similar to the embodiment of FIG. 18 with the addition of a WDM filter 108 which receives the light from the optical fiber cable 14 and then transmits this light to the cell light detector 106. In FIG. 20, which may be seen as an opto-electronic circuit with WDM filter array, the circuit 20 includes the light source 100, the light source driver 102 and the reference light detector 104, however, the light received from the optical fiber cable 14 is received by a WDM filter array 110 and then transmitted to a cell light detector array 112 before being transmitted to the electrical signal generator 22.

Without changing the generality of the diagrams in FIGS. 18 to 20, the “Light In” and “Light Out” can be a single input/output when the system operates in reflection mode. In this configuration, the input and reflection optical signals can be separated by an optical circulator 114 such as schematically shown in FIG. 21.

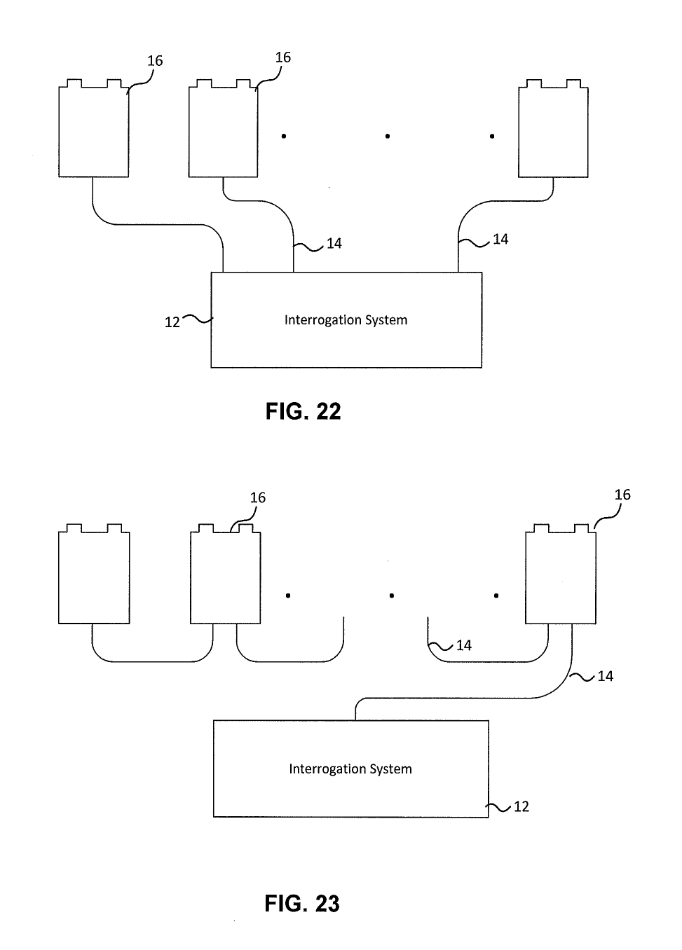

Turning to FIG. 22, a schematic diagram of how multiple energy storage devices may be monitored via a single sensor interrogation system is shown. The sensor interrogation system 12 is connected to a set of energy storage devices, such as battery cells 16 via individual optical fiber cables 14 such that the single interrogation system may be used to demodulate the signals from multiple battery cells with or without daisy chaining the battery cells. In FIG. 23, another multiple energy storage device set-up is shown. In this embodiment, the sensor interrogation system 12 is connected via a single optical fiber cable 14 to multiple battery cells 16 whereby the single strand is embedded or integrated within multiple cells and is preferably used in a reflection mode. In one embodiment of demodulation, which may be based on the time of flight (also known as TDM), the light source sends pulses of light and de-multiplex the sensors based on the time it takes for the pulses to be reflected from each sensor and return to the detector or the time it takes for the pulse to propagate to the other end of the optical fiber cable. In another embodiment of demodulation, each sensor in the battery cell has a specific operating wavelength which is different from the other sensors and are demodulated using Wavelength Division Multiplexing (WDM).

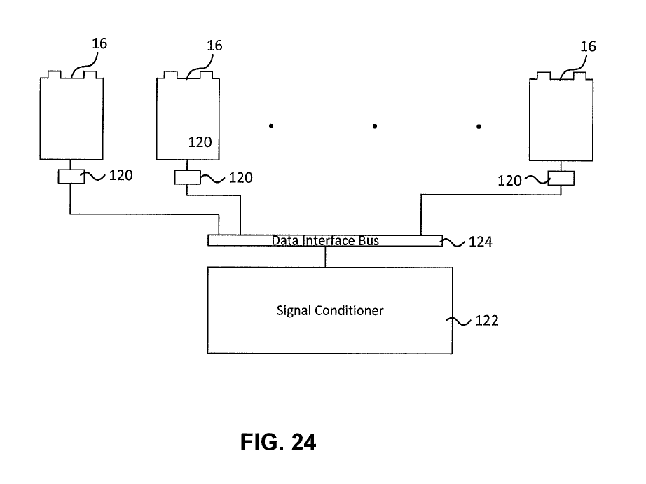

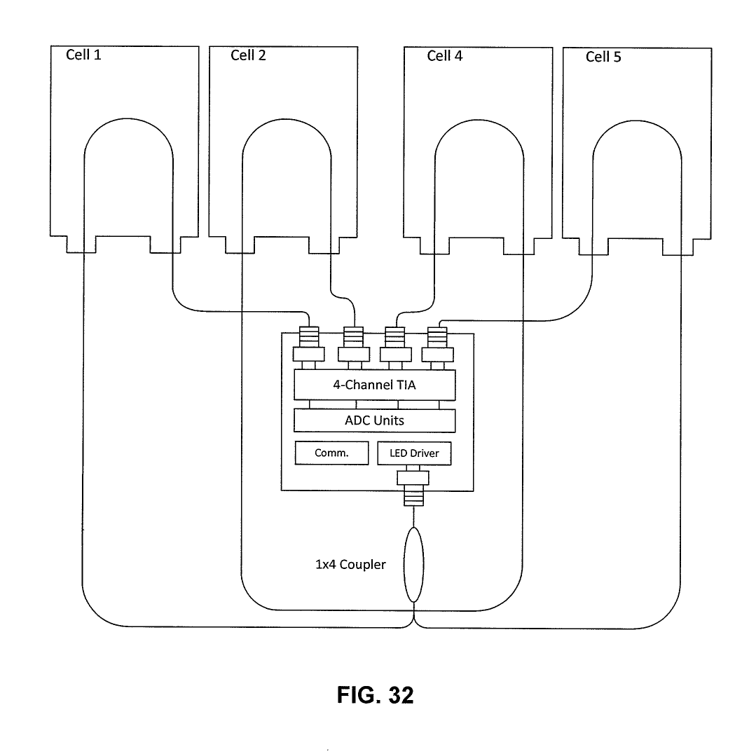

In yet another embodiment, as shown in FIG. 24, the opto-electronic circuit 20 is integrated in a microchip 120 and is packaged or associated with a single energy storage device, or battery cell 16. The microchips 120 are connected to a signal conditioner 122 through a digital and/or analog bus via a cable. Although not shown in a daisy chain set up, it will be understood that the battery cells may also be set up in a daisy chain. The connection between the opto-electronic micro-chips and the signal conditioner can also be maintained via wireless communication. In this wireless embodiment, the signal conditioner may contain the power supply, signal converter, micro-processor, and data communication module. Also, in another embodiment, a battery module (or a combination of multiple battery cells) can be monitored using one interrogation or micro-chip unit (as shown in FIG. 32). In this configuration, one light source is used to illuminate all sensors and the sensors optical are individually connected to photo-detectors. In this configuration, the amplification (i.e., TIA) and the signal converter (ADC) units have the capability to handle multiple channels.

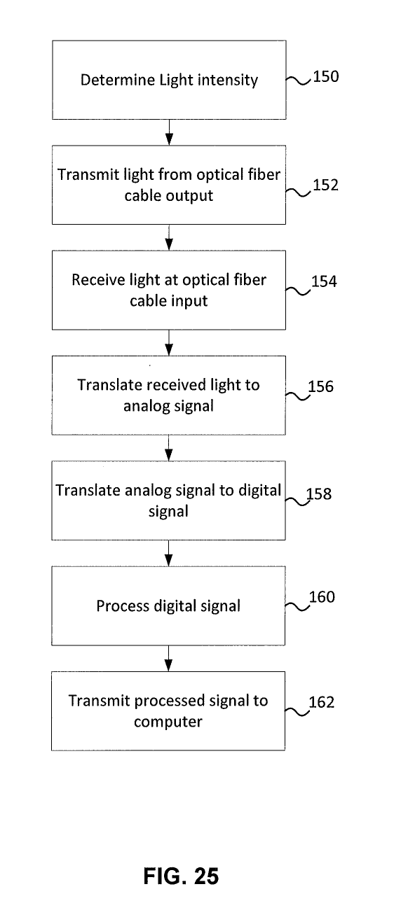

Turning to FIG. 25, a flowchart outlining a method of monitoring battery characteristics is shown. Firstly, a light intensity level is determined by the microprocessor (150). This light intensity level represents the level of light that is delivered by the sensor interrogation system into the energy storage device, such as a battery cell, through the fiber optic cable. This light intensity level may also be entered by a user via the external computer or may be pre-stored within the micro-processor such that it is a default value. Without changing the generality of this embodiment, the microprocessor may use the reference photo-detector 104 signal as feedback to control the light intensity via the light source driver. Light is then transmitted out of the optical fiber cable output (152) whereby it travels along the optical fiber cable into the battery cell and then returns and is received at the optical fiber cable input (154). In the transmission mode embodiment of FIG. 1, the light is transmitted through the light output end 14b and received at the light input end 14a. In the reflection mode embodiment of FIG. 4, the light is transmitted out of the dual light input and light output end 44a.

The received light is then translated into an analog signal (156), preferably by the opto-electronic circuit and then the analog signal is translated into a digital signal (158), preferably by the signal converter such as an Analog to Digital Converter (ADC).

The digital signal then undergoes preliminary processing (160) in order to prepare the digital signal for transmission by the data communication module. The processed signal is then transmitted to the computer (162) via the data communication module such that a user (via the external processor) can analyze the characteristics of the battery cell based on the measurements obtained by the apparatus 10.

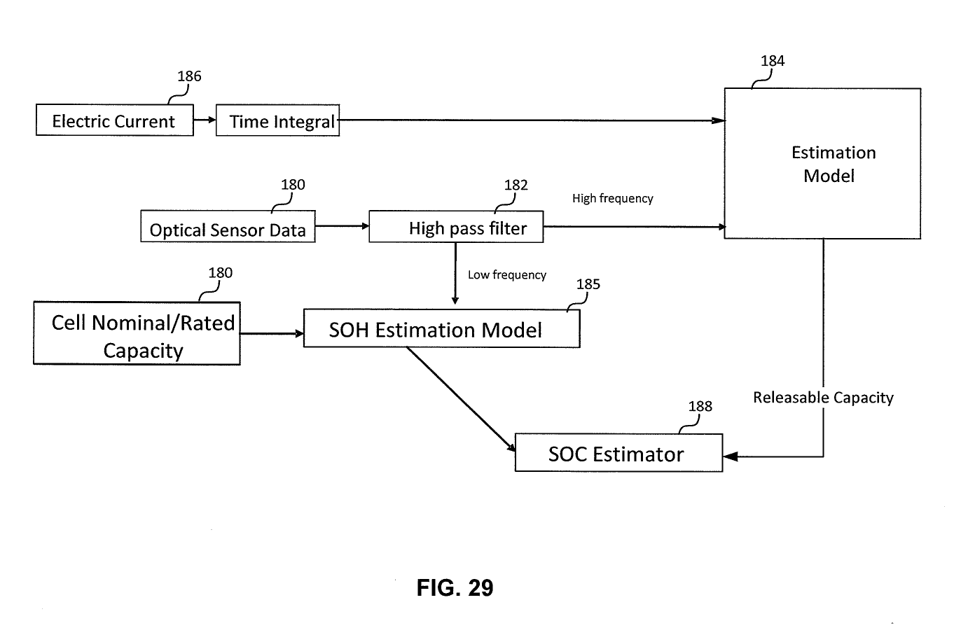

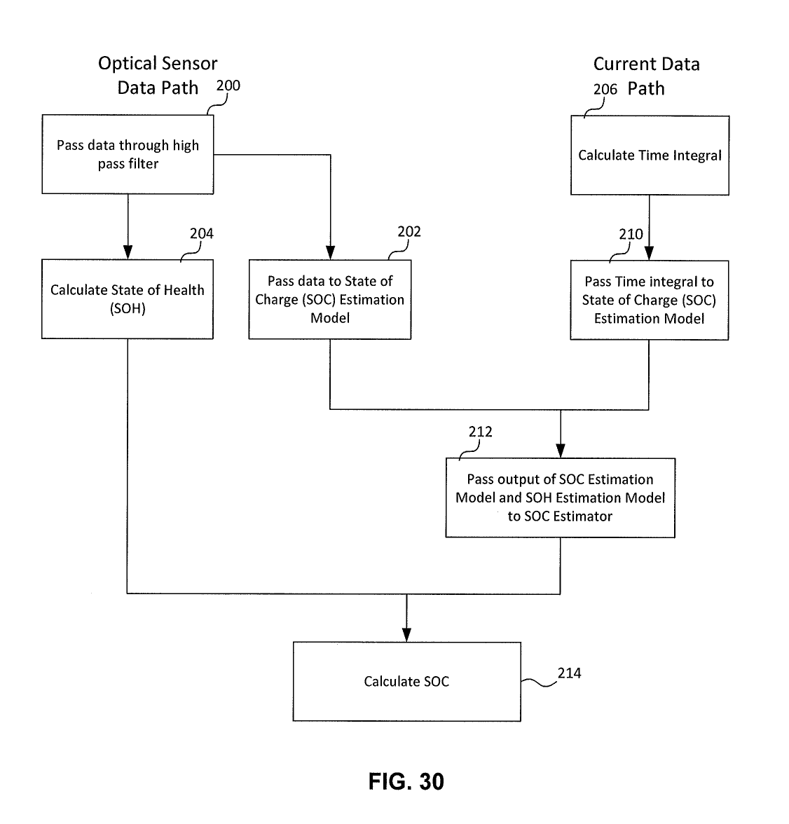

Turning to FIG. 29, a schematic diagram of a system for the estimation of energy storage device characteristics is shown while FIG. 30 provides a flowchart of a method for estimating the energy storage device characteristics using the system of FIG. 29. In one embodiment, the system is integrated within the computer, such as the external processor. After the signal (which may be seen as optical sensor data) has been transmitted to the processor from the sensor interrogation system, the optical sensor data undergoes further processing in order to obtain the characteristics of the energy storage device, such as a battery cell. This processing may take various forms.

In one embodiment, the optical sensor data 180 is passed through a high pass filter 182 (200) which filters the data 180 into two parts (a low frequency component and a high frequency component) and transmits the high frequency component of the filtered signal to a SOC estimation model 184 (202) and transmits the low frequency component of the filtered signal a SOH estimation model 185 so that the SOH of the energy storage device can be calculated (204). Concurrently with the optical sensor data transmission, current data or an electric current 186 is processed to produce a time integral (206) and then passed through a high pass filter 187 to the estimation model 184 (210). An output of the estimation model (seen as a releasable charge) is passed to a SOC estimator 188 (212) and then the SOC calculated (214). A sample calculation is disclosed below.

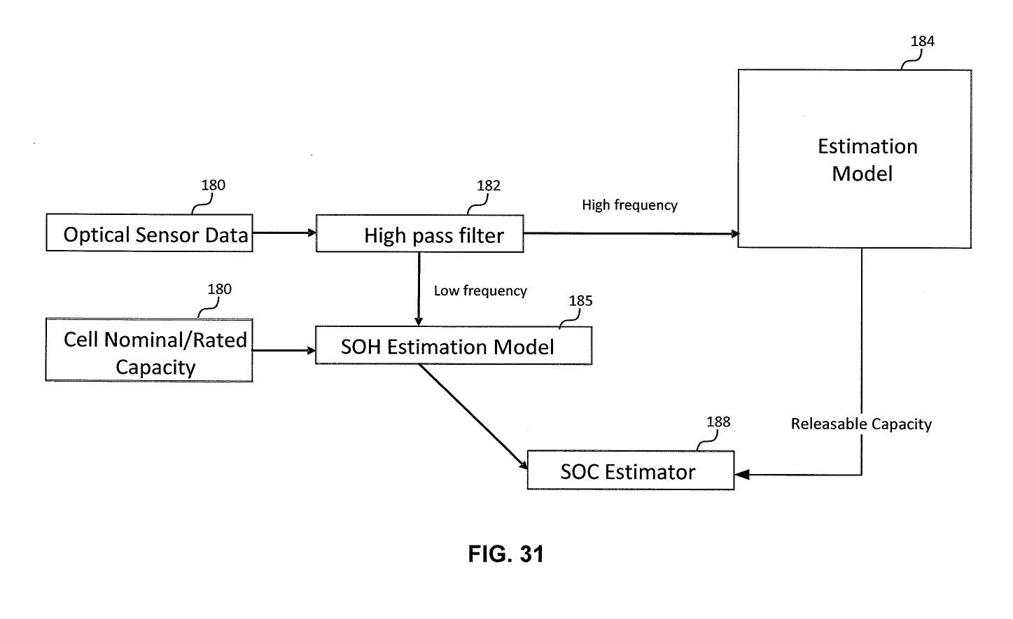

In another embodiment, as schematically shown in FIG. 31, the optical sensor data 180 is passed through the high pass high pass filter 182 (200) which filters the data 180 into high and low frequency components and transmits the high frequency component signal to the SOC estimation model 184 (202) and the low frequency component to the SOH estimation model 185 so the SOH can be calculated (204). An output of the estimation model 184 is passed to the SOC estimator 188 along with an output from the SOH estimation model and the SOC of the battery calculated (214).

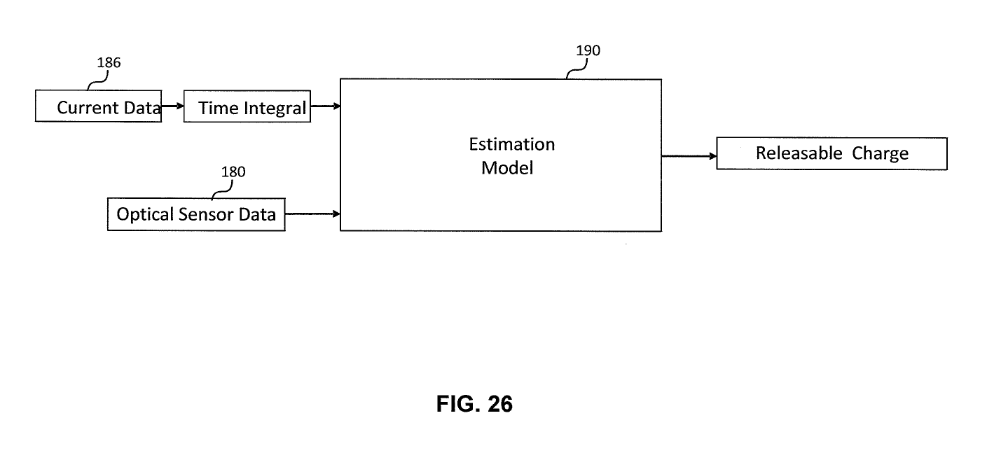

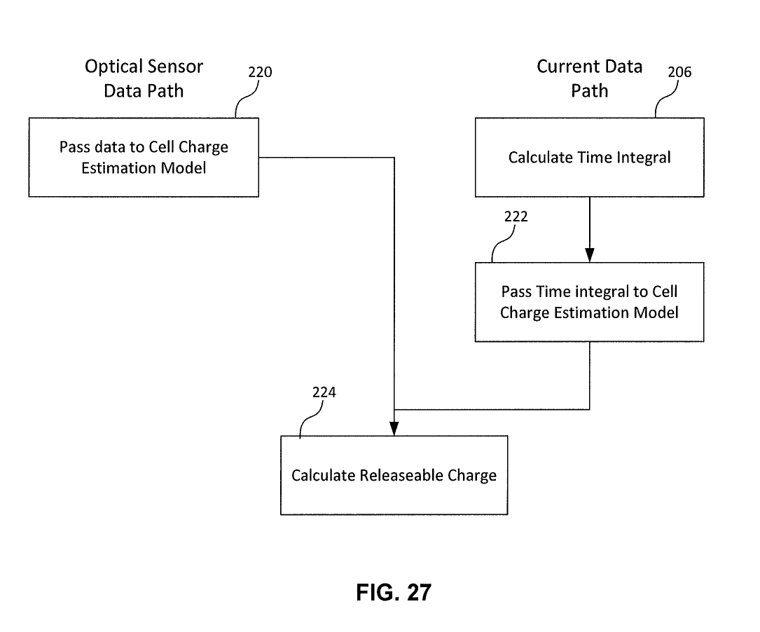

Another embodiment of a method for calculating cell charge is schematically shown in FIG. 26 while FIG. 27 provides a flowchart of a method for calculating the cell charge characteristics using the system of FIG. 26. The optical sensor data 180 is transmitted to a cell charge estimation model 190 (220). Concurrently, current data 186 is processed to produce a time integral (206) and then passed to the cell charge estimation model 190 (222). The output of the cell charge estimation model provides a releasable capacity characteristic measurement (224).

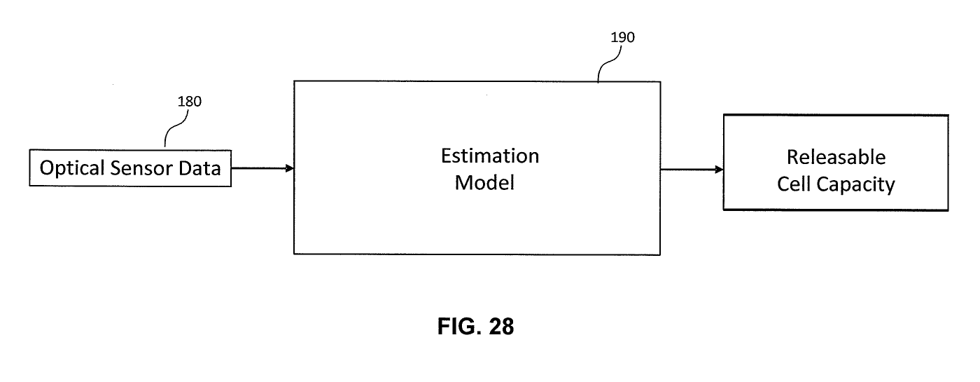

In yet a further embodiment or apparatus for calculating cell charge, as schematically shown in FIG. 28, the optical sensor data 180 is transmitted to the cell charge estimation model 190 (220) which then outputs a releasable capacity characteristic measurement (224).

In one example of calculation (which may be used for each of the embodiments of FIGS. 29 and 31), the optical sensor data along with electric current data are fed into the estimation model to estimate the amount of releasable capacity (which may be seen as the amount of energy left in the battery or storage device or the remaining battery charge) in the energy storage device, or battery cell. Before implementing the estimation model, the estimation model 184 or 190 should to be trained to configure the parameters. Different models can be realized for battery characteristics estimation including, but not limited to, static and dynamic models. In one embodiment, the static model is an algebraic relation or equation correlating the releasable battery capacity at any instance of time to an instantaneous value of the battery electric current and optical sensor data. In a dynamic model, the releasable capacity is a function of the current and previous values of the battery electric current and optical sensor data.

In one example of the dynamic or estimation model, the battery releasable capacity at any sample time denoted by k(c(k)) is a function of the optical sensor signal (pₒₚₜ(k)) and cell current (i(k)) such that:

c(k)=f(c(k−1), c(k−2), . . . , c(k−d_{c}), pₒₚₜ(k), pₒₚₜ(k−1), pₒₚₜ(k−2), . . . , pₒₚₜ(k−dₒ), i(k), i(k−1), i(k−2), . . . , i(k−dᵢ))

In another configuration of this model, the battery releasable capacity is only a function of the optical sensor signal:

c(k)=f(c(k−1), c(k−2), . . . , c(k−d_{c}), pₒₚₜ(k)pₒₚₜ(k−1), pₒₚₜ(k−2), . . . , pₒₚₜ(k−dₒ))

Different types of dynamic models can be realized for estimation including, but not limited to, a linear autoregressive (ARX) model or a non-linear autoregressive model (NARX). Numerical methods such as neural networks and fuzzy logic may be used for training these models and configuring model parameters.

In one embodiment, an estimation model block or estimation model (such as shown in FIG. 26, 28, 29, or 31) may include a set of numerical models in the form of computer code to estimate the releasable capacity of the battery cell in real time. The estimation model uses optical sensor data with or without the electric current measurement to perform the releasable capacity, or energy, estimation. The estimation model may be in the form of static or dynamic correlation between the optical sensor signal, electric current and the releasable energy. As will be understood, the estimation model differs for each energy storage device.

In a static model, the releasable capacity at any time is directly correlated to the optical sensor data at that time or to the combination of electric current measurement data and optical sensor data at that time. In a dynamic model, the releasable energy at any time is a series of the optical sensor data at the present time and previous measurements over time or a combination of the optical sensor data and electric current data at the present time and the previous measurements over time. In other words, the releasable energy is a function of successive measurements of optical signal and electric current over a time interval (as shown in the equation above).

In one embodiment, the estimation model utilizes real-time data acquisition at a certain frequency. The dynamic model can be linear or nonlinear.

In order for the estimation model to be operational, the estimation model has to be tuned. The tuning process may include recording data and optimizing or improving the model parameters to reduce or minimize estimation errors. Different tuning methods can be used including, but not limited to, fuzzy logic, genetic algorithm, Kalman filtering, etc.

Experiments have shown that the optical sensor data can also be used for the estimation of the state of health (SOH) of the storage device or battery. One method of performing SOH estimation is by implementing a filter to decouple high frequency and low frequency components. It has been observed that a gradual decay in the response of the sensor can be correlated to battery aging. There are other methods for SOH estimation. In another method, the total change in the optical sensor signal in each full charge/discharge cycle reduces as the battery ages.

The SOC is calculated by using the battery nominal capacity (i.e., the capacity of a new battery), SOH, and releasable energy at any time.

Another way of estimating SOC is by obtaining the correlation between the optical signal and the battery cell open circuit voltage (OCV). In Lithium-ion batteries there is a one-to-one relationship between SOC and OCV such that the optical signal can be directly used for SOC estimation.

In operation, by comparing a releasable capacity, such as a maximum value, obtained from the estimation after full discharge and a rated capacity or nominal capacity of the battery cell (specified by the manufacturer), the SOH of the battery can be estimated. By comparing the releasable capacity at any instance of time with the maximum or expected releasable capacity of the cell, the actual SOC can be estimated. Maximum releasable capacity may be defined as the actual capacity of the battery after being used. This capacity level is generally the same as rated capacity for a brand new battery or energy storage device. As the battery decays, this capacity is reduced.

In another embodiment, the estimation model can be reconfigured to estimate the state of health (SOH) directly from the optical sensor signal (such as schematically shown in FIGS. 29 and 31). In this configuration, the optical sensor signal data is processed using a high pass filter. Experimental results have shown that a gradual low frequency decay of the optical signal can be correlated to battery aging and at the end to the SOH of the battery. The high frequency components, isolated from low frequency components, are fed into an estimation model to estimate the releasable battery capacity as explained above. To estimate the releasable capacity, the electric current data may be used in combination with the optical sensor data. Having the SOH and the releasable capacity estimations, the SOC of the battery can be estimated. This estimation model also needs to be trained before implementation. Similar calculations and model estimation procedures may be performed for the apparatus of FIGS. 26 and 28.

Therefore, in general, within an energy storage device, in transmission mode, as the light travels through the energy storage device, the light interacts with the energy storage device at the modified areas within the optical fiber cable such that this amended or changed light is then returned to the interrogation system. This change in light characteristics provides the necessary information relating to energy storage device characteristics and is seen as the optical sensor data.

Within the energy storage device, in reflection mode, as the light travels through the energy storage device, the light interacts with the energy storage device at the modified areas within the optical fiber cable. This interaction causes the properties of the light within the optical fiber cable to change. When the light reaches the second end of the optical cable, the light is reflected back towards the interrogation system such that this amended or changed light is then returned to the interrogation system for further processing. This change in light characteristics provides the necessary information relating to energy storage device characteristics which is seen as the optical sensor data.

In another configuration, the optical sensor signal is used to estimate the open circuit voltage of the cells which is correlated to the SOC.

In some embodiments, the micro-processer and the data communication module are a single component rather than being individual components. Also, in other embodiments, the micro-processor may be a component external to the sensor interrogation system.

Without changing the generality of these embodiments, the optical fiber cable can be replaced by a multitude of optical waveguides integrated in an optical micro-chip.

The above-described embodiments are intended to be examples only. Alterations, modifications and variations can be effected to the particular embodiments by those of skill in the art without departing from the scope of intended protection.

1. A system for monitoring energy storage device characteristics comprising:
an energy storage device;
an optical fiber cable having a first end and a second end whereby a portion of the optical fiber cable is embedded within the energy storage device; and
a sensor interrogation system, the sensor interrogation system connected to at least one of the first end or second end of the optical fiber cable.

2. The system of claim 1 wherein the first end of the optical fiber cable is connected to the sensor interrogation system and the second end of the optical fiber cable is connected to a reflective membrane cavity within the battery cell.

3. The system of claim 1 wherein the first end and the second end of the optical fiber cable is connected to the sensor interrogation system.

4. The system of claim 1 wherein the optical fiber cable is embedded within an anode of the battery cell.

5. The system of claim 1 wherein the optical fiber cable is embedded within a cathode of the battery cell.

6. The system of claim 1 wherein the optical fiber cable is embedded between an anode and a separator of the battery cell.

7. The system of claim 1 wherein the optical fiber cable is embedded between a cathode and a separator of the battery cell.

8. The system of claim 5 wherein a portion of cladding is removed from at least one section of the optical fiber cable.

9. The system of claim 6 wherein a portion of cladding is removed from at least one section of the optical fiber cable.

10. The system of claim 7 wherein a portion of cladding is removed from at least one section of the optical fiber cable.

11. The system of claim 8 wherein the at least one section is coated with an active material, inscribed optical circuits, or which are sensitive to changes in the energy storage device.

12. The system of claim 9 wherein the at least one section is coated with an active material, inscribed optical circuits, or which are sensitive to changes in the energy storage device.

13. The system of claim 10 wherein the at least one section is coated with an active material, inscribed optical circuits, or which are sensitive to changes in the energy storage device.

14. The system of claim 8 for sensing at least one of the following energy storage device characteristics:
temperature,
releasable capacity,
state-of-charge (SOC),
state-of-health (SOH),
electrolyte chemistry,
chemical properties,
volume change of battery, and
battery components chemical properties.

15. The system of claim 1 further comprising a central processing unit for receiving an output from the sensor interrogation system and analyzing the data.

16. The system of claim 1 wherein the optical fiber cable includes at least one sensor.

17. A method of determining energy storage device characteristics comprising:
transmitting light through an optical fiber cable embedded within the energy storage device;
sensing an amount of light from the optical fiber cable after the light has travelled through the optical fiber cable;
translating the amount of light to a digital signal; and
processing the digital signal through an algorithm to determine energy storage device characteristics.

18. The method of claim 17 wherein translating the amount of light to a digital signal comprises:
translating the amount of light to an analog signal; and
translating the analog signal to the digital signal.

19. The method of claim 17 wherein processing the digital signal comprises:
transmitting the digital signal through a high pass filter to separate the digital signal into a high frequency component and a low frequency component.

20. The method of claim 19 further comprising:
transmitting the high frequency component to a state of charge (SOC) estimation model.

21. The method of claim 19 further comprising:
transmitting the low frequency component to a state of health (SOH) estimation model.

22. The method of claim 17 where the digital signal is processed to estimate the open circuit voltage (OCV).

23. The method of claim 17, where the digital signal and the electric current measurements are processed simultaneously to estimate the releasable capacity.

24. The system of claim 11 for sensing at least one of the following energy storage device characteristics:
temperature,
releasable capacity,
state-of-charge (SOC),
state-of-health (SOH),
electrolyte chemistry,
chemical properties,
volume change of battery, and
battery components chemical properties.
